(19) United States
(12) Patent Application Publication
(10) Pub. No.: US 2013/0242641 A1
(43) Pub. Date: Sep. 19, 2013

(54) SEMICONDUCTOR DEVICE

(71) Applicant: ELPIDA MEMORY, INC., Tokyo (JP)

(72) Inventor: Kiyoshi NAKAI, Tokyo (JP)

(73) Assignee: ELPIDA MEMORY, INC., Tokyo (JP)

(21) Appl. No.: 13/795,582

(22) Filed: Mar. 12, 2013

(30) Foreign Application Priority Data
Mar. 14, 2012 (JP) 2012-057126

(51) Int. Cl. G11C 13/00

(52) U.S. Cl. CPC G11C 13/0069
USPC 365/148

(57) ABSTRACT

A semiconductor device includes: a plurality of variable resistance memory cells; a plurality of bit lines each of which is connected to one end of each of the plurality of variable resistance memory cells; a common source line that is connected to the other ends of the plurality of variable resistance memory cells in common; a source line driver that supplies a potential to the common source line; and a controller that variably controls a current supplied to the common source line by the source line driver.

### REFERENCE TO RELATED APPLICATION

This application is based upon and claims the benefit of the priority of Japanese patent application No. 2012-057126, filed on Mar. 14, 2012, the disclosure of which is incorporated herein in its entirety by reference thereto.

### TECHNICAL FIELD

The present invention relates to a semiconductor device. Particularly, the present invention relates to a semiconductor device comprising variable resistance elements as memory elements.

### BACKGROUND

As a present-day non-volatile semiconductor memory device, a flash memory is extensively used. However, investigations into a variety of large-capacity semiconductor memory devices, capable of taking the place of the flash memories, are now going on. In particular, a variable resistance element ReRAM (Resistance Random Access Memory), which has a laminate structure including a lower electrode, metal oxides, and an upper electrode, and changes the resistance characteristics by adding electrical stress between the lower electrode and upper electrode, becomes the center of attention. Since the variable resistance elements maintain their resistance-changed states even after power down, the variable resistance elements may operate as non-volatile memories.

In writing data in a variable resistance element, two different sorts of write are needed. One is a write of changing a high resistance state to a low resistance state. The other is a write of changing a low resistance state to a high resistance state. In explanations below, the write for changing a high resistance state to a low resistance state is referred to as SET write, and the write for changing a low resistance state to a high resistance state is referred to as RESET write.

Further in the present description, it is assumed that a low resistance state is “1”, and a high resistance state is “0”. Namely, SET write is a write operation of writing “1”, and RESET write is a write operation of writing “0”.

The operations of SET write and RESET write may be classified into a unipolar type and a bipolar type. In the unipolar operation, the write is executed as a voltage is applied to the variable resistance element in the same direction for SET write and RESET write. Whereas, in the bipolar operation, the write is executed as a voltage is applied to the variable resistance element in the opposite direction for SET write and RESET write. By referring to FIG. 8, a write operation of the bipolar type will now be described. FIG. 8 plots a voltage applied across the electrodes of the variable resistance element as the abscissa, and a current value flowing between both ends at this time as the ordinate. It is assumed that the variable resistance element is initially in a high resistance state. If, in this high resistance state, a positive voltage VSET is applied across both terminals of the variable resistance element (point A in FIG. 8), the variable resistance element is set by SET write to a low resistance state from the high resistance state (transition from point A to point B of FIG. 8). The maximum current flowing at this time is denoted by ICOMP.

On the other hand, during RESET write in which the variable resistance element is changed from the low resistance state to the high resistance state, a voltage is applied to in a reverse direction of the write in SET write. That is to say, a voltage VRESET is applied to the variable resistance element in the low resistance state in an opposite direction of the voltage for SET write (point C in FIG. 8. The current flowing at this time is denoted by IRST). This resets the variable resistance element from the low resistance state so that the variable resistance element reverts to the high resistance state (transition from the point C to a point D in FIG. 8). In reading out from the variable resistance element, it is determined whether the variable resistance element is in a low resistance state or in a high resistance state by checking a current flowing when a voltage equal to or lower than VSET is applied to the variable resistance element.

As described above, it is necessary that the voltage is applied to the variable resistance element in the opposite direction for SET write and RESET write. Thus, when a memory cell array is constituted by arranging a plurality of variable resistance elements, it is necessary that a bit line is connected to one end of each of the variable resistance elements; a source line is connected to the other end of each of the variable resistance elements; and potentials of the bit line and the source line connected to each of the variable resistance elements are controlled, respectively.

Generally, in order to apply a voltage in opposite directions for SET write and RESET write, the following method can be considered. That is, source lines are fixed to GND potential; a bit line is set to a potential Vd (corresponding to VSET in FIG. 8) during SET write; and the bit line is set to a potential −Vd during RESET write (corresponding to VRESET in FIG. 8). However, in the above method, the bit line transits between the positive potential +Vd and the negative potential −Vd. That is, the transition in the bit line voltage is 2Vd. There is a problem in which a large amplitude difference is needed in the bit line, and a negative potential generation circuit that generates the negative potential −Vd is needed.

In order to solve the above problem, Patent Literature 1 discloses a method of setting bias voltages supplied to each of terminals of variable resistance elements. Namely, during a standby, each of the terminals is pre-charged to a reference potential Vp that is less than a setting value Vd; during SET write, one terminal is set to the setting value Vd, and the other terminal is set to GND potential. By the above setting, the forward directional bias voltage Vd is applied across both terminals of the variable resistance element. On the other hand, during RESET write, inversely to the time of SET write, one terminal is set to GND potential, and the other terminal is set to the setting value Vd. By the above setting, a reverse directional bias voltage −Vd is applied across both terminals of the variable resistance element by taking the setting voltage Vd at the other terminal as a reference.

From the above, in the semiconductor device described in Patent Literature 1, such an effect is brought about that a voltage transition at each terminal of the variable resistance elements can be reduced to Vd, and a negative potential generation circuit is unnecessary.
[Patent Literature 1]:
JP Patent Kokai Publication No. JP2007-234133A, which corresponds to U.S. Pat. No. 7,518,903B2.

### SUMMARY

The disclosure of the above cited Patent Literature is incorporated herein in its entirety by reference thereto. The analysis below will be presented in the view point of the present disclosure.

In constituting a memory cell array in which a plurality of variable resistance elements are disposed in a matrix form, source lines are needed for respective bit lines. Thus, a layout size is expanded, which causes high cost. Thus, it is desired that the layout size is reduced by unifying the source lines.

Here, if the source lines are unified, there is a problem in which a capacitance included in a common source line is extremely large. Generally, a wiring having a large capacitance can be driven by using a large-sized driver. However, if the common source line is driven by the large-sized driver, there is a risk in which a peak current flowing in the common source line is excessive. If the peak current is excessive, wirings on the current path must be thick. Further, there are difficulties in increasing the number of contact plugs.

Patent Literature 1 discloses a method of applying potentials of a source line and a bit line by reversing their potentials in opposite direction for SET write and RESET write. However, Patent Literature 1 does not address the above issue regarding unifying source lines.

As described above, in a semiconductor device including a memory cell array in which a plurality of variable resistance elements are disposed, if a layout size is reduced by unifying the source lines, there is a problem to be solved.

A semiconductor device according to a first aspect of the present disclosure includes the following constituent elements. That is to say, the semiconductor device includes: a plurality of variable resistance memory cells; a plurality of bit lines each of which is connected to one end of each of the plurality of variable resistance memory cells; a common source line that is connected to the other ends of the plurality of variable resistance memory cells in common; a source line driver that supplies a potential to the common source line; and a controller that variably controls a current supplied to the common source line by the source line driver.

The meritorious effects of the present disclosure are summarized as follows without limitation thereto. According to the first aspect of the present disclosure, in a semiconductor device including a memory cell array in which a plurality of variable resistance elements are disposed, even if the source lines are unified, there is provided a semiconductor device in which a peak current can be suppressed.

### BRIEF DESCRIPTION OF THE DRAWINGS

FIG. 1 is a block diagram showing a semiconductor device in accordance with a first exemplary embodiment of the present disclosure.

FIG. 2 is a block diagram showing a memory cell array of the semiconductor device in accordance with the first exemplary embodiment of the present disclosure.

FIG. 3 is a block diagram showing a memory cell mat of the semiconductor device in accordance with the first exemplary embodiment of the present disclosure.

FIG. 4 is a block diagram showing Y switches, a write amplifier, a source line driver, and variable resistance memory cells of the semiconductor device in accordance with the first exemplary embodiment of the present disclosure.

FIG. 5 is a circuit diagram of a (one-bit) Y switch of the semiconductor device in accordance with the first exemplary embodiment of the present disclosure.

FIG. 6 is a timing chart showing an operation of the semiconductor device in accordance with the first exemplary embodiment of the present disclosure.

FIGS. 7A and 7B are illustrations for explaining the operation of the semiconductor device in accordance with the first exemplary embodiment of the present disclosure.

FIG. 8 is an illustration for explaining a write operation in a variable resistance element.

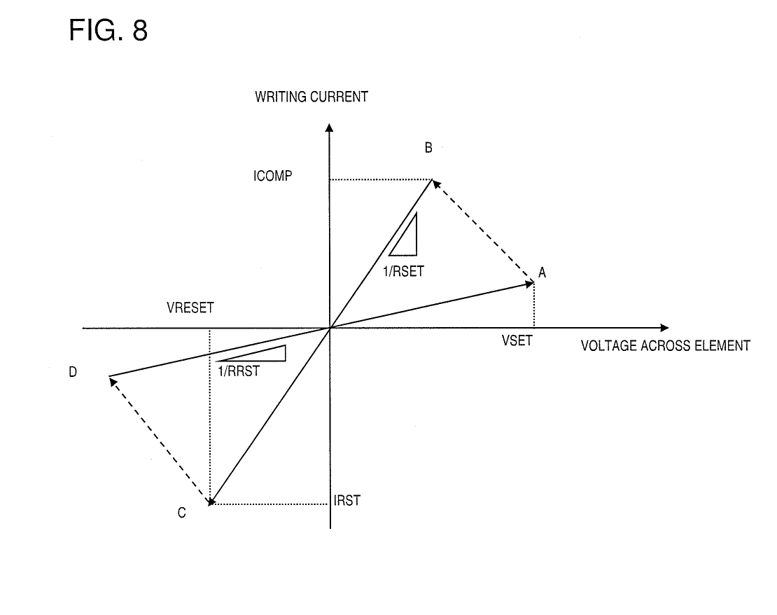

FIG. 9 is a block diagram showing a memory cell mat of a semiconductor device in accordance with a second exemplary embodiment of the present disclosure.

FIG. 10 is a block diagram showing Y switches, a write amplifier, a source line driver, and variable resistance memory cells of the semiconductor device in accordance with the second exemplary embodiment of the present disclosure.

FIG. 11 is a circuit diagram of a (one-bit) Y switch of the semiconductor device in accordance with the second exemplary embodiment of the present disclosure.

FIG. 12 is a timing chart showing an operation of the semiconductor device in accordance with the second exemplary embodiment of the present disclosure.

FIG. 13 is a timing chart showing an operation during RESET write in the semiconductor device in accordance with the second exemplary embodiment of the present disclosure.

FIG. 14 is a timing chart showing an operation during SET write in the semiconductor device in accordance with the second exemplary embodiment of the present disclosure.

### PREFERRED MODES

An outline of preferred modes of the present disclosure will be described. Meanwhile, drawing-reference symbols referred to in the following outline are shown only as examples to assist understanding, and are not intended to limit the present disclosure to the illustrated modes.

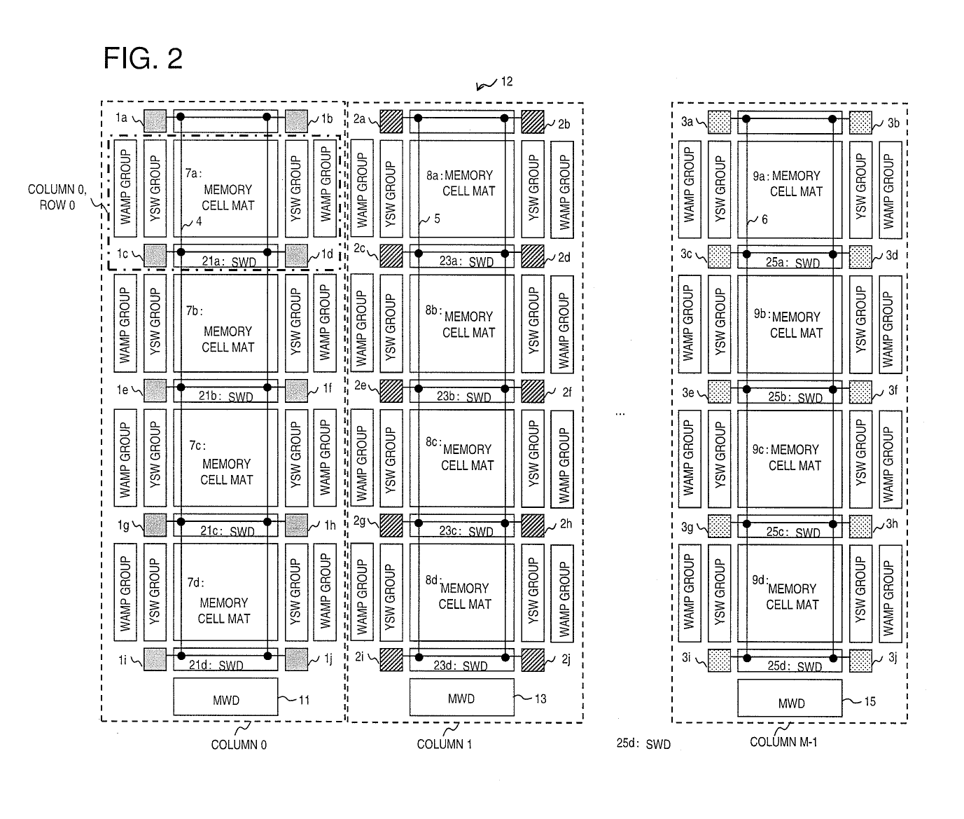

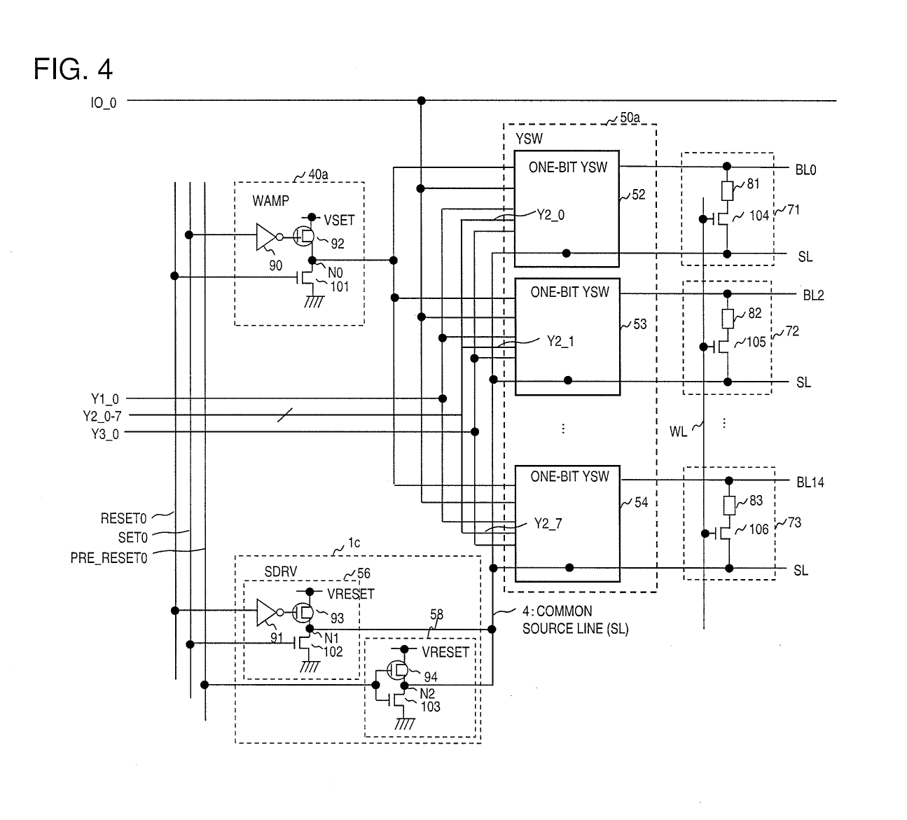

As shown in FIG. 4, a semiconductor device according to one exemplary embodiment of the present disclosure includes the following constituent components. That is to say, the semiconductor device includes: a plurality of variable resistance memory cells (71 to 73 in FIG. 4); a plurality of bit lines (BL0, BL2, BL14 etc. in FIG. 4) each of which is connected to one end of each of the plurality of variable resistance memory cells; a common source line (4(SL) in FIGS. 4; 4, 5 and 6 in FIG. 2 etc.) that is connected to the other ends of the plurality of variable resistance memory cells in common; a source line driver (1c in FIG. 4; 1a to 1j, 2a to 2j, and 3a to 3j in FIG. 2) that supplies a potential to the common source line; and a controller that variably controls a current supplied to the common source line by the source line driver.

According to the above constitution, when SET write or RESET write is performed, a current supplied to the common source line (4, 5 and 6 in FIG. 2 etc.) can be reduced at the timing of switching a voltage that controls the common source line (4, 5 and 6 in FIG. 2 etc.), which makes it possible to suppress a peak current.

The exemplary embodiments will now be explained with reference to the drawings.

### First Exemplary Embodiment

### Constitution of the First Exemplary Embodiment

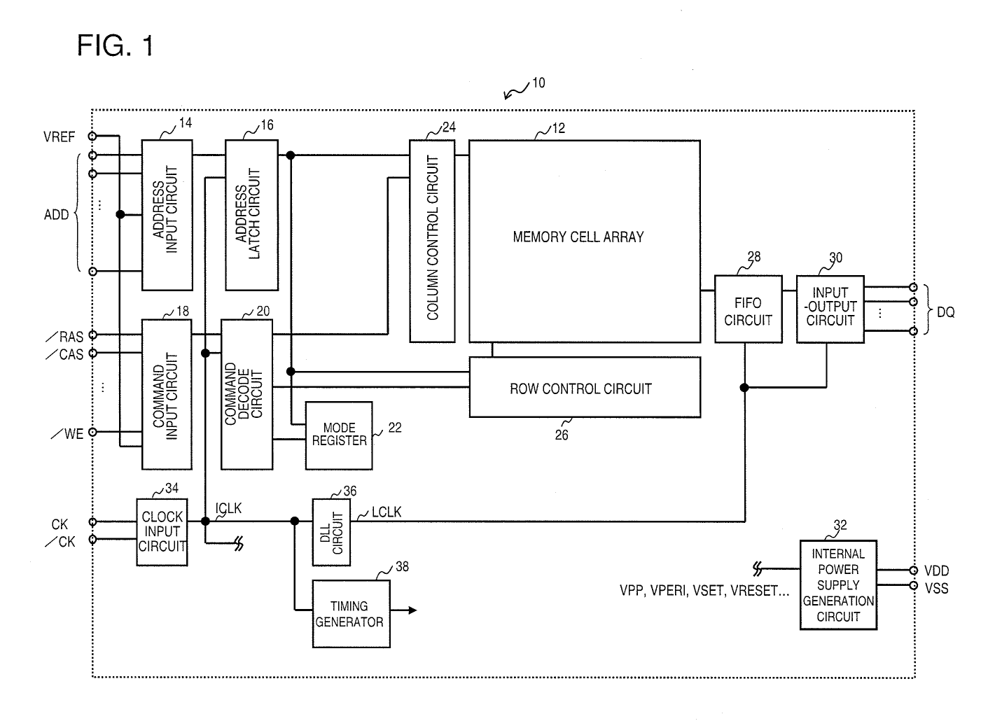

FIG. 1 is a block diagram of an entire semiconductor device 10 in accordance with the first exemplary embodiment of the present disclosure. In FIG. 1, a memory cell array 12 includes a plurality of variable resistance memory cells (71 to 73 in FIG. 4) that are two-dimensionally disposed. Each of the variable resistance memory cells includes a variable resistance element (ReRAM) (81 to 83 in FIG. 4) and a cell transistor (104 to 106 in FIG. 4). Each of the variable resistance elements stores a high resistance state “0” or a low resistance state “1”, and works as a non-volatile memory element. NMOS transistors are preferable for the cell transistors (104 to 106 in FIG. 4). After a variable resistance memory cell is selected in the memory cell array 12 to be accessed, the following three operations are performed: SET write for changing from a high resistance state to a low resistance state; RESET write for changing from a low resistance state to a high resistance state; and read out a resistance state.

In FIG. 1, blocks other than the memory cell array 12 controls the above three operations for the memory cell array 12.

First, an address input circuit 14 receives an address ADD of a variable resistance memory cell to be accessed. Next, an address latch circuit 16 latches the received address ADD, separates the ADD into a row address ADD_row and a column address ADD_column, and supplies the ADD_row and the ADD_column to a row control circuit 26 and a column control circuit 24, respectively.

Here, the row control circuit 26 includes a row decoder (not shown) that decodes a row selection signal from the row address ADD_row. A (sub) word line (it is referred to as “selective (sub) word line” below) selected by the above row selection signal becomes active. The column control circuit 24 includes a column decoder (not shown) that decodes a column selection signal from the column address ADD_column. A bit line (it is referred to as “selective bit line” below) selected by the above column selection signal becomes active.

A plurality of variable resistance memory cells in the memory cell array 12 are disposed at intersections of the plurality of (sub) word lines and the plurality of bit lines. Among them, a variable resistance memory cell connected to both the selective (sub) word line and the selective bit line is selected to be accessed. Concretely, for example, if BL0 in FIG. 4 is a selective bit line, and a (sub) word line WL in FIG. 4 is a selective (sub) word line, the cell transistor 104 is in an on state, and a write operation is performed by applying a voltage between a common source line 4 and the selective bit line BL0, and flowing a current into a variable resistance element 8 of a variable resistance memory cell 71.

The clock input circuit 34 receives complimentary external clock signals CK, /CK externally supplied to the semiconductor device 10, and generates an internal clock ICLK to supply the ICLK to a DLL (Delay Locked Loop) circuit 36 and a timing generator 38. The timing generator 38 generates various timing signals needed in the semiconductor device 10 based on the internal clock ICLK to supply the timing signals to each unit. Meanwhile, in the present description, “/” in signal names shows that the signal is active if the signal is Low level. The DLL circuit 36 generates a clock signal LCLK from the internal clock ICLK to supply the clock signal LCLK to a FIFO circuit 28 and an input-output circuit 30. The FIFO circuit 28 and the input-output circuit 30 operate in synchronization with the supplied clock signal LCLK.

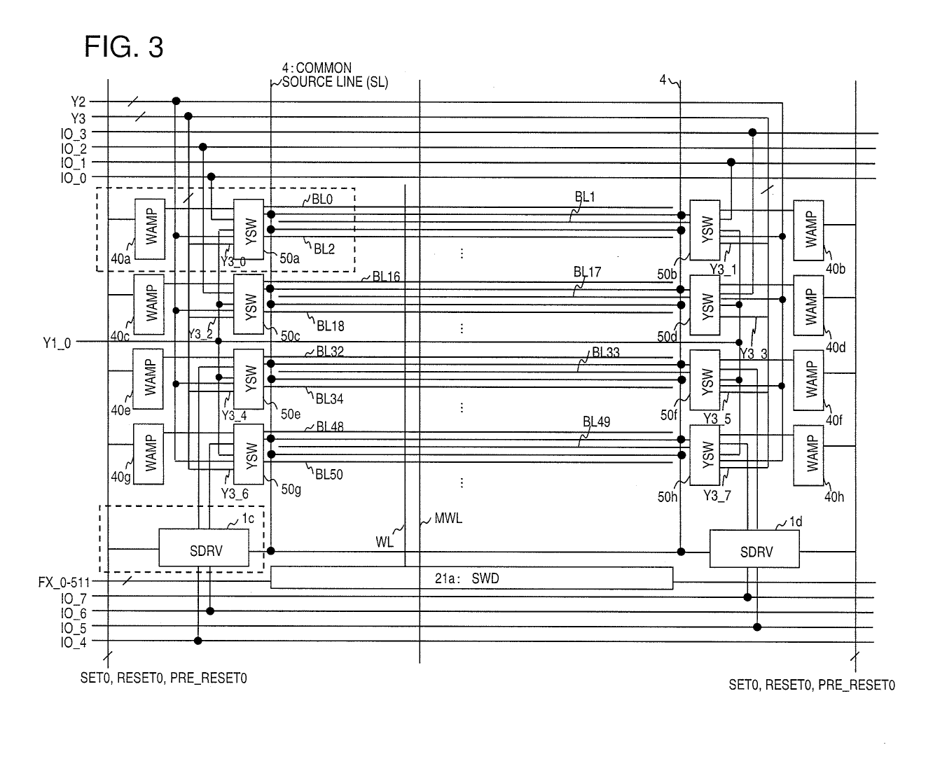

A data input-output terminal DQ is connected to the input-output circuit 30. If the data input-output terminal DQ receives write-data, the write-data is taken to the input-output circuit 30 in synchronization with the clock signal LCLK. The input-output circuit 30 is connected to the FIFO circuit 28, and converts the taken write-data into series data as needed to output the data to IO lines (IO_0-7 in FIG. 3) in the memory cell array 12 via the FIFO circuit 28. Then, it is controlled that a write amplifier (WAMP; 40a in FIG. 4 etc.) is conducted to the selective bit line via a Y switch (50a in FIG. 4 etc.) based on the data of the IO lines.

Next, a command input circuit 18 receives a row address strobe signal /RAS, a column address strobe signal /CAS, and a write enable signal /WE etc. as control signals. A command decode circuit 20 decodes these signals /RAS, /CAS, /WE etc. to output a control signal needed for executing the decoded command to each unit in the semiconductor device 10. An operation mode of the semiconductor device 10 is set in a mode register 22.

Next, an internal power supply generation circuit 32 receives power supply voltages VDD, VSS externally supplied, and generates voltages VPP, VPERI, VSET, VRESET etc. needed in each unit of the semiconductor device 10 to supply these voltages to each unit. Here, the voltage VSET is supplied to the write amplifier (40a in FIG. 4 etc.) to be used during SET write. The voltage VRESET is supplied to the source line driver (1c in FIG. 4 etc.) to be used during RESET write.

Next, by referring to FIG. 2, the constitution of the memory cell array 12 will be described in detail. As shown in FIG. 2, the memory cell array 12 includes a plurality of memory cell mats (7a to 7d, 8a to 8d, 9a to 9d). Here, the plurality of memory cell mats are two-dimensionally disposed. FIG. 2 shows the memory cell array 12 including 4 rows by M columns memory cell mats as an example. However, the arrangement of the memory cell mats is not limited to 4 rows by M columns, and any arrangements are possible.

As shown in FIG. 2, 4 rows by M columns memory cell mats are separated into regions in column unit, and a unified source line is used for each of the regions. Concretely, a common source line 4 is disposed in the 0-column memory cell mats; a common source line 5 is disposed in the 1-column memory cell mats; and a common source line 6 is disposed in the (M−1)-column memory cell mats.

FIG. 2 illustrates that five source lines in row direction and two source lines in column direction are disposed in one region of column unit. However, practically, the common source line (4, 5, 6) is formed by a common diffusion layer or one-layer plane.

Y switch groups (YSW group) and write amplifier groups (WAMP group) are disposed at both sides of each of the memory cell mats.

As for the word lines, main word lines and sub word lines constitute a hierarchical structure. A main word line driver (MWD) is disposed at each of the column units; a sub word driver (SWD) is disposed at each of the memory cell mats. In this hierarchical structure, sub word lines are directly connected to the variable resistance memory cells.

It is preferred that at least one source line driver is disposed at each of the memory cell mats from a point of steady current supply. Thus, as shown in FIG. 2, in the first exemplary embodiment, source line drivers (1a to 1j, 2a to 2j, 3a to 3j) are disposed at both sides of a sub word driver SWD (21a to 21d, 23a to 23d, 25a to 25d) in each of the memory cell mats, respectively. However, the arrangement of the source line drivers is not limited to the above arrangement, and any arrangement is possible.

Next, by referring to FIG. 3, a constitution of a portion (inside a dashed-dotted line in FIG. 2) of a single memory cell mat 7a, i.e., (row 0, column 0)-memory cell mat will be described in more detail. In FIG. 3, the memory cell mat 7a includes, e.g., 512×512 variable resistance memory cells that are two-dimensionally disposed. The row address ADD_row consists of 9 bits, and 6 bits of the 9 bits are used for selecting one of the main word lines MWL and remaining 3 bits are used for selecting one of the row selection signals FX 0-7 supplied to a sub word line driver 21a.

On the other hand, the column address ADD_column also consists of 9 bits. After the column address ADD_column is separated into ADD_column_h, ADD_column_m, and ADD_column_1 each of which consists of 3 bits, they are decoded, respectively. Here, ADD_column_h is higher-order 3 bits in the ADD_column; ADD_column_1 is lower-order 3 bits in the ADD_column; and ADD_column_m is intermediate bits other than the ADD_column_h and ADD_column_1. And Y1_0-7 are eight column selection signals obtained by decoding the ADD_column_h; Y2_0-7 are eight column selection signals obtained by decoding the ADD_column_m; and Y3_0-7 are eight column selection signals obtained by decoding the ADD_column_1.

A variable resistance memory cell disposed at an intersection of a selective (sub) word line according to the above-mentioned row selection signals FX_0-7 and a selective bit line according to the above-mentioned column selection signals Y1_0-7, Y2_0-7, and Y3_0-7 is accessed.

As shown in FIG. 3, in two write amplifier groups (WAMP groups) disposed at both sides of the memory cell mat 7a in FIG. 2, one write amplifier group includes four write amplifiers (40a, 40c, 40e, and 40g), and the other write amplifier group includes four write amplifiers (40b, 40d, 40f, and 40h).

In FIG. 3, in two Y switch groups (YSW groups) disposed at both sides of the memory cell mat 7a in FIG. 2, one Y switch group includes four Y switches (50a, 50c, 50e, and 50g), and the other Y switch group includes four Y switches (50b, 50d, 50f, and 50h).

FIG. 3 illustrates only source line drivers 1c, 1d among four source line drivers (1a, 1b, 1c, and 1d) disposed adjacently to the memory cell mat 7a in FIG. 2 (although source line drivers 1a, 1b are not shown in FIG. 3, in fact, they are connected adjacently to the memory cell mat 7a).

A set signal SET0, a reset signal RESET0, and a pre-reset signal PRE_RESET signal are supplied as control signals from a controller (not shown) of a higher-order unit to the source line drivers (1c, 1d) controlling a potential of the common source line 4. On the other hand, the set signal SET0 and the reset signal RESET0 are supplied as control signals from the controller (not shown) of the higher-order unit to the write amplifier (40a-40h) controlling a potential of the selective bit line.

In FIG. 3, eight IO lines (IO_0-7) are disposed. The eight IO lines (IO_0-7) maintain signals corresponding to respective bits of write-data supplied from the external input-output terminal DQ via the input-output circuit 30 and the FIFO circuit 28. If, after the 8 bit write operation is finished, next 8 bits write data is supplied from the external input-output terminal DQ, the signals of the eight IO lines (IO_0-7) are updated.

Next, a relation of the column selection signals Y1, Y2, Y3 and the selective bit line will be described in detail. The 512 bit lines BL_0-511 are classified into eight groups each of which includes 64 bit lines. A first group includes BL_0-63; a second group includes BL_64-127; a third group includes BL_128-191; a fourth group includes BL_192-255; a fifth group includes BL_256-319; a sixth group includes BL_320-383; a seventh group includes BL_384-447; and an eighth group includes BL_448-511.

The column selection signals Y1_0-7 determine which group is selected among the above-mentioned first to eighth groups. As shown in FIG. 3, the column selection signal Y1_0 is supplied to the eight Y switches (50a-50h) connected to the bit lines BL_0-63 that belong to the first group. From the above, if the column selection signal Y1_0 is active, the bit lines BL_0-63 in the first group is selected. Similarly, the second group, the third group, . . . , the eighth group are selected by the column selection signals Y1_1, Y1_2, . . . , Y1_7, respectively.

Next, the column selection signals Y3_0-7 determine which Y switch is selected among the eight Y switches in each group. For example, as shown in FIG. 3, in the first group, the column selection signals Y3_0 to Y3_7 are supplied to eight Y switches 50a-50h, respectively; and a Y switch connected to a wiring whose signal is in an active state among the column selection signals Y3_0-7 is selected.

As shown in FIG. 3, even bit lines and odd bit lines are classified and wired to left-sided Y switches and right-sided Y switches one by one, respectively. Each of the Y switches is connected to eight bit lines. Concretely, the Y switch 50a is connected to the bit line BL0, BL2, . . . , and BL14. The Y switch 50b is connected to the bit line BL1, BL3, . . . , and BL15. The Y switch 50c is connected to the bit line BL16, BL18, . . . , and BL30. The Y switch 50d is connected to the bit line BL17, BL19, . . . , and BL31. The Y switch 50e is connected to the bit line BL32, BL34, . . . , and BL46. The Y switch 50f is connected to the bit line BL33, BL35, . . . , and BL47. The Y switch 50g is connected to the bit line BL48, BL50, . . . , and BL62. The Y switch 50h is connected to the bit line BL49, BL51, . . . , and BL63.

Next, in each Y switch, the column selection signals Y2_0-7 supplied to the Y switch determine which bit line is selected. For example, in the Y switch 50a, according to the column selection signals Y2_0-7 a single bit line is selected among the bit line BL0, BL2, . . . , BL14. Concretely, if the Y2_0 is active, the bit line BL0 is selected; if the Y2_1 is active, the bit line BL2 is selected; and if the Y2_7 is active, the bit line BL14 is selected.

As described above, according to the column selection signals Y1, Y2, Y3, a single bit line is selected as a selective bit line. However, in FIG. 3, a plurality of bit lines may be selected as selective bit lines. For example, if the column selection signals Y3_0-7 are all set to be High level (active), a single bit line per each of the eight Y switches in some group can be set as a selective bit line. By the above setting, eight variable resistance memory cells can be accessed at the same time.

As shown in FIG. 3, since a write amplifier (40a to 40h etc.) per each of the Y switches (50a to 50h etc.) is provided, it is capable of supplying voltages to the plurality of selective bit lines.

Next, by referring to FIG. 4, a constitution of the source line driver 1c, the write amplifier 40a, the Y switch 50a, and variable resistance memory cells (71 to 73) will be described in more detail. FIG. 4 is a block diagram showing a region of a dashed line box in FIG. 3 in detail.

First, in FIG. 4, the source line driver 1c includes a first source line driver circuit 56, and a second source line driver circuit 58. Both an output node N1 of the first source line driver circuit 56 and an output node N2 of the second source line driver circuit 58 are connected to the common source line 4.

The first source line driver circuit 56 includes a PMOS transistor 93, an NMOS transistor 102, and an inverter circuit 91. The PMOS transistor 93, and the NMOS transistor 102 are connected in series between the voltage source VRESET and the ground. Concretely, source of the PMOS transistor 93 is connected to the voltage source VRESET; drain of the PMOS transistor 93 and drain of the NMOS transistor 102 are connected to the node N1 in common; and source of the NMOS transistor 102 is connected to the ground. Gate of the PMOS transistor 93 is connected to a wiring of the reset signal RESET0 via the inverter circuit 91. Gate of the NMOS transistor 102 is connected to a wiring of the set signal SET0.

The second source line driver circuit 58 includes a PMOS transistor 94, and an NMOS transistor 103. The PMOS transistor 94 and the NMOS transistor 103 are connected in series between the voltage source VRESET and the ground. Concretely, source of the PMOS transistor 94 is connected to the voltage source VRESET; drain of the PMOS transistor 94 and drain of the NMOS transistor 103 are connected to the node N2 in common; and source of the NMOS transistor 103 is connected to the ground. Gate of the PMOS transistor 94 and gate of the NMOS transistor 103 are connected to a wiring of the pre-reset signal PRE_RESET0 in common.

Meanwhile, current drive capability of the PMOS transistor 94 in the second source line driver circuit 58 is set to be smaller than that of the PMOS transistor 93 in the first source line driver circuit 56. Concretely, for example, a channel width of the PMOS transistor 94 is set to be smaller than that of the PMOS transistor 93. Similarly, current drive capability of the NMOS transistor 103 in the second source line driver circuit 58 is set to be smaller than that of the NMOS transistor 102 in the first source line driver circuit 56. Concretely, for example, a channel width of the NMOS transistor 103 is set to be smaller than that of the NMOS transistor 102.

Next, the write amplifier 40a includes a PMOS transistor 92, an NMOS transistor 101, and an inverter circuit 90. The PMOS transistor 92 and the NMOS transistor 101 are connected in series between the voltage source VSET and the ground. Concretely, source of the PMOS transistor 92 is connected to the voltage source VSET; drain of the PMOS transistor 92 and drain of the NMOS transistor 101 are connected to a node N0 in common; and source of the NMOS transistor 101 is connected to the ground. Gate of the PMOS transistor 92 is connected to a wiring of the set signal SET0 via the inverter circuit 90. Gate of the NMOS transistor 101 is connected to a wiring of the reset signal RESET0.

Next, a constitution of the Y switch 50a will be described. The Y switch 50a includes eight one-bit Y switches (52 to 54). The common source line 4, the output of the write amplifier 40a (voltage of node N0), the column selection signals Y1_0, Y3_0 are supplied to the one-bit Y switches (52 to 54). The column selection signals Y2_0, Y2_1, . . . , Y2_7 are supplied to the eight one-bit Y switches (52 to 54), respectively.

One output terminals of the one-bit Y switches (52 to 54) are connected to the bit line BL0, the bit line BL2, . . . , the bit line BL14, respectively. The other output terminals of the one-bit Y switches (52 to 54) outputs the input common source line 4 (SL) as it is.

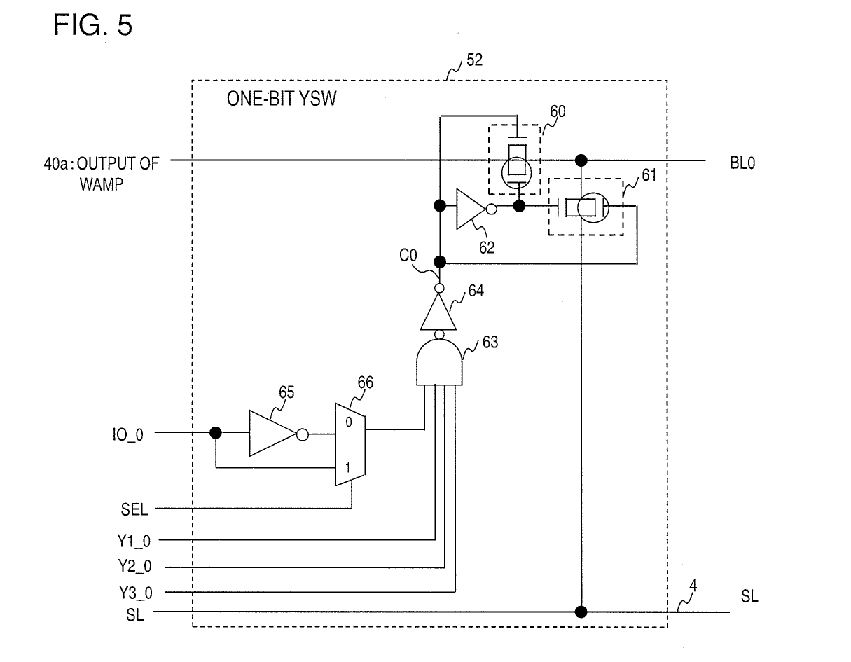

Next, by referring FIG. 5, the constitution of the one-bit Y switch 52 will be described in detail. The one-bit Y switch 52 includes a bit line selection switch 60, a bit line common source line connection switch 61, inverter circuits 62, 64, 65, a NAND circuit 63, and a selector 66. Here, both the bit line selection switch 60 and the bit line common source line connection switch 61 are transfer gates constituted by a PMOS transistor and an NMOS transistor. The bit line selection switch 60 is a switch that controls conductive/non-conductive between the output of the write amplifier 40a and the bit line BL0. On the other hand, the bit line common source line connection switch 61 is a switch that controls conductive/non-conductive between the common source line 4 and the bit line BL0.

Both the bit line selection switch 60 and the bit line common source connection switch 61 are controlled in a complementary manner by a control signal C0 that is an output of the inverter circuit 64. Concretely, when the control signal C0 is at High level, the bit line selection switch 60 is in a conductive state, whereas the bit line common source line connection switch 61 is in a non-conductive state. As the result, the bit line BL0 is conductive to the write amplifier 40a. On the other hand, when the control signal C0 is at Low level, the bit line selection switch 60 is in a non-conductive state, whereas the bit line source line connection switch 61 is in a conductive state. As the result, the bit line BL0 is conductive to the common source line 4 (SL).

Next, a constitution of portion regarding generation of the control signal C0 will be described. The column section signals Y1_0, Y2_0, and Y3_0 are supplied to three input terminals of the NAND circuit 63. The signal IO_0 in the IO line is supplied to one input terminal of the selector 66 via the inverter 65; and the signal IO_0 in the IO line is supplied to the other input terminal of the selector 66 as it is. A control signal SEL is supplied as a selection control signal for the selector 66 from the controller (not shown) of the higher-order unit. The control signal SEL is a control signal that is a Low level during RESET write, a High level during SET write. And output of the selector 66 is supplied to the input terminal of the NAND circuit 63.

During RESET write, since the signal in IO line is active when IO_0=0 (Low level), the selector 66 is constituted so that the signal passing through the inverter 65 is selected. From the above, if SEL=0, IO_0=0 and the column selection signals Y1_0=Y2_0=Y3_0=1, the control signal C0=1, so that the bit line BL0 is conductive to the write amplifier 40a, and becomes a selective bit line. On the other hand, if the signal in IO line IO_0=1 (High level), the control signal C0=0, so that the bit line BL0 does not become a selective bit line, and is conductive to the common source line 4.

On the other hand, during SET write, since the signal in IO line is active when IO_0=1 (High level), the selector 66 is constituted so that the signal IO_0 is selected. From the above, if SEL=1, IO_0=1 and the column selection signals Y1_0=Y2_0=Y3_0=1, the control signal C0=1, so that the bit line BL0 is conductive to the write amplifier 40a, and becomes a selective bit line. On the other hand, if the signal in IO line IO_0=0 (Low level), the control signal C0=0, so that the bit line BL0 does not become a selective bit line, and is conductive to the common source line 4.

### Operation of the First Exemplary Embodiment

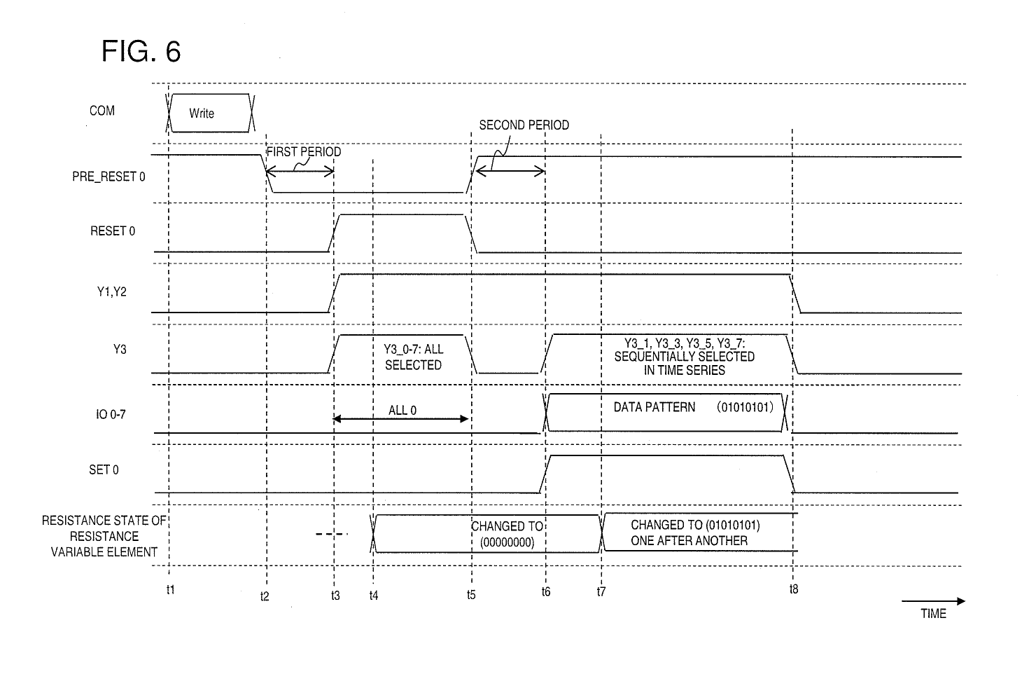

Next, an operation of the first exemplary embodiment will be described in detail with reference to FIG. 6. FIG. 6 is a timing chart showing an operation of the semiconductor device in accordance with the first exemplary embodiment. FIG. 6 shows a command (COM), a pre-reset signal PRE_RESET0, a reset signal RESET0, column selection signals Y1, Y2, a column selection signal Y3, signals in IO lines IO_0-7, a set signal SET0, and resistance state of the selected variable resistance element, from the top to the bottom, respectively.

In FIG. 6, in the memory cell mat including 512×512 variable resistance memory cells illustrated in FIG. 3, it is assumed that 8 bit data (01010101) is written in a predetermined address. Here, the respective bits of the 8 bit data (01010101) correspond to signals of IO_0, IO_1, . . . , IO_6, IO_7 in the internal IO lines, respectively, from the left bit to the right bit. It is also assumed that the column selection signals Y3_0-7 are all set to be active, so that each bit of the above 8 bit data is written to each of eight variable resistance memory cells selected by the higher-bit column selection signals Y1, Y2.

However, if each bit of the 8 bit data (01010101) is written in order, the source line drivers have to be reverse-driven per bit. Thus, if source lines are unified, the above method is inefficient. Thus, in the first exemplary embodiment, first, the variable resistance elements of the selected eight variable resistance memory cells are changed to the high resistance state by performing RESET write for all bits (00000000) regardless of write-data pattern. After that, SET write is performed for bits of SET write (bits that are changed to the low resistance state). Concretely, SET write is performed for IO_1, IO_3, IO_5, and IO_7.

Next, each of operations at the timings t1 to t8 in FIG. 6 will be described in detail. First, before receiving a write command (Write), an active command (not shown) is issued, so that a (sub) word line is selected. Then, as shown in FIG. 6, the write command (Write) is issued at time t1.

Next, during an initial state of time t1 to t2, all the column selection signals Y1, Y2, Y3 are in a non-selective state, i.e., a Low level. Thus, since the control signals C0 in FIG. 5 for all cells are at Low level, the bit line common source line connection switch in each of the one-bit Y switches is conductive, so that all the bit lines BL_0-511 are conductive to the common source line 4. And in the initial state, it is assumed that the pre-reset signal PRE_RESET0 is set to be High level; the reset signal RESET0 is set to be Low level; and the set signal SET0 is set to be Low level. From the above, during the time t1 to t2, only the NMOS transistor 103 is in an on state among the transistors of the source line drivers (1c etc.), so that the potentials of the common source line 4 and all the bit lines BL_0-511 maintain a Low level.

Next, at time t2, the pre-reset signal PRE_RESET0 is controlled to transit to a Low level, so that the NMOS transistor 103 becomes an off state and the PMOS transistor 94 becomes an on state in the second source driver circuit 58. From the above, the common source line 4 is pre-charged via the PMOS transistor 94 from the voltage source VRESET. The time length of a predetermined first period (t2 to t3 in FIG. 6) of pre-charge to complete the pre-charge to the common source line 4 is calculated based on the wiring capacitance etc. of the common source line 4 in advance to be set.

At time t2, the common source line 4 potential transits from 0 to VRESET. However, since the common source line 4 is driven by the PMOS transistor 94 having small current driving capability, an occurrence of peak current due to the potential transition from 0 to VRESET can be suppressed. Meanwhile, at this timing, all the bit lines BL_0-511 are pre-charged to the VRESET potential.

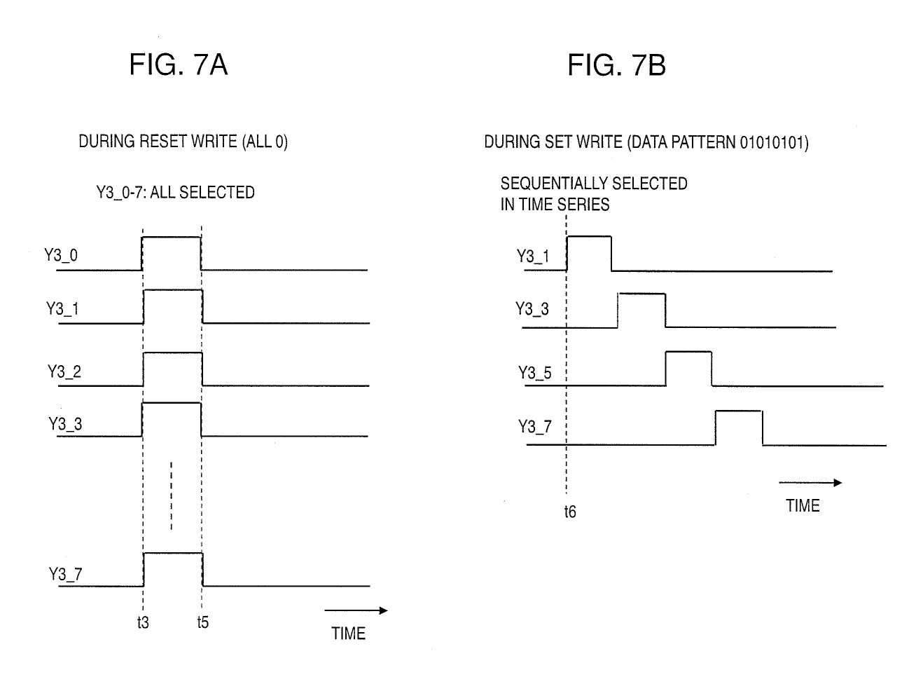

Next, RESET write starts at time t3. The column selection signals Y1, Y2 are set, respectively, and as shown in FIG. 7A, all the column selection signals Y3_0-7 are set to be a High level (active), so that eight bit lines are set as selective bit lines. To perform RESET write to all the bits, the signals IO_0-7 in the eight IO lines are all set to be 0.

And the PMOS transistor 93 of the first source line driver circuit 56 becomes an on state by controlling the reset signal RESET0 to transit to a High level, so that the source line driver becomes a state in which a current is supplied to the common source line 4 via the PMOS transistor 93 from the voltage source VRESET. Meanwhile, the PMOS transistor 94 of the second source line driver circuit 58 is still in the on state. However, since the current driving capability of the PMOS transistor 93 is larger than that of the PMOS transistor 94, the current supplied to the common source line 4 is driven mainly by the first source line driver circuit 56 during this period.

Since the control signals C0 are at High level in the eight Y switch circuits (52 in FIG. 5 etc.) selected by the column selection signals Y1, Y2, Y3, the bit line selection switches 60 become conductive, so that the eight selective bit lines are conductive to the write amplifiers (40a to 40h), respectively. Since the NMOS transistors 101 of the write amplifiers (40a to 40h) becomes an on state, the output nodes N0 assume 0 potential.

From the above, during the period of time t3 to t5, the eight selective bit lines are at 0 potential, and bit lines other than the eight selective bit lines and the common source line 4 are at VRESET potential. Since the selective sub word line WL is at High level, cell transistors corresponding to the eight selective bit lines are conductive, so that a current flows in the direction from the common source line 4 to the selective bit lines through the variable resistance elements in the selected eight variable resistance memory cells.

Here, the selected eight variable resistance elements do not transit to the high resistance state immediately at the timing t3, but start transiting to the high resistance state at the timing t4. The time length of the period of t3 to t4 is a parameter determined by the characteristic of the used ReRAM.

Next, after the selected eight variable resistance elements transit to the high resistance state, the reset signal RESET0 and the column selection signals Y3_0-7 which have been controlled to transit during the RESET write are recovered to the Low level at the time t5. And the pre-reset signal PRE_RESET0 is controlled to transit to a High level. In the source line drivers (1c etc.), only the NMOS transistor 103 of the second source line driver circuit 58 is in an on state. And charges that have been charged to the common source line 4 are discharged via the NMOS transistor 103, so that the potential of the common source line 4 transits from the VRESET potential to 0 potential. The time length of a predetermined second period (t5 to t6 in FIG. 6) of discharge to complete the discharge of the charges that have been charged to the common source line 4 is calculated based on the wiring capacitance of the common source line 4 etc. in advance to be set. At this time, since the charges that have been charged to the common source line 4 are discharged via the transistor 103 having small current driving capability, an occurrence of peak current due to the potential transition from VRESET to 0 can be suppressed. Meanwhile, all the bit lines BL0-511 are also set to 0 potential during this period.

Next, SET write starts at time t6. The signals IO_0-7 in the eight IO lines output the signals of the data pattern (01010101) of the write-data, and maintain the signals. And the NMOS transistor 102 becomes an on state in the NMOS transistor 102 of the first source line driver circuit 56 by controlling the set signal SET0 to transit to a High level, so that the source line driver circuits become a state in which 0 potential is supplied to the common source line 4 via the NMOS transistor 102. Meanwhile, the NMOS transistor 103 of the second source line driver circuit 58 is still in the on state. However, since the current driving capability of the NMOS transistor 102 is larger than that of the NMOS transistor 103, the current drawn from the common source line 4 is mainly caused by the first source driver circuit 56 during this period.

In SET write starting from the time t6, SET writes are performed one by one for each bit of the SET write bits (i.e., bits which are set to be in the low resistance state) among the eight bits. The SET write bits are signals maintained in the IO_1, IO_3, IO_5, and IO_7 among signals of the eight IO lines. The column selection signals Y3 corresponding to the four signals are Y3_1, Y3_3, Y3_5, and Y3_7. Thus, as shown in FIG. 7B, among the column selection signals Y3, the Y3_1, Y3_3, Y3_5, and Y3_7 are set to be active one by one in time series.

In the four Y switch circuits (52 in FIG. 5 etc.) selected by the column selection signals Y1, Y2, Y3_1, Y3_3, Y3_5, and Y3_7, the control signals C0 are at High level during the selection, so that the bit line selection switches 60 are conductive, and the selective bit lines are conductive to the write amplifiers (40a to 40h). Since the PMOS transistor 92 is in an on state in the write amplifier (40a to 40h), the output nodes N0 are at the VSET potential.

From the above, during the period of time t6 to t8, a selective bit line selected in time series among the four selective bit lines is the VSET potential, whereas other bit lines and the common source line 4 are at 0 potential. Since the selected sub word line is at High level, a cell transistor corresponding to the selective bit line selected one by one in time series is conductive, so that the SET write is performed to the variable resistance element by flowing a current in the direction from the selective bit line selected in time series to the common source line 4 via the variable resistance element. That is, as shown in FIG. 7B, SET write is performed sequentially by controlling to transit Y3_1, Y3_3, Y3_5, and Y3_7 among the column selection signals Y3 to a High level one by one.

Each of the selected four variable resistance elements does not transit to the low resistance state immediately after starting flowing through the variable resistance element, but after some period it starts transiting to the low resistance state. As shown in FIG. 6, a first resistance variable element starting the SET write at the time t6 starts transiting to the resistance state at time t7. The time length of the period of t6 to t7 is a parameter determined by the characteristic of the used ReRAM.

As mentioned above, the SET write to the four variable resistance elements is finished. And after completing the transition to the desired resistance state, the signals that have been controlled to transit during the SET write are recovered at time t8, so that the signals are set to be the same as in the initial state of the time t1.

Next, the effects of the first exemplary embodiment will be described. According to the semiconductor device 10 in accordance with the first exemplary embodiment, the layout size can be reduced, and the cost can be low by constituting the common source line 4 obtained by unifying source lines. On the other hand, wiring capacitance of the common source line 4 becomes large by unifying the wirings, which causes harmful effect in which an excessive peak current flows. Thus, in the first exemplary embodiment, when the common source line 4 potential is changed from 0 potential to the VRESET potential prior to the RESET write, the common source line 4 potential is pre-charged by the second source line driver circuit 58 having low current driving capability (first period during time t2 to t3 in FIG. 6). From the above, when the potential of the common source line 4 is controlled to transit, the peak current can be suppressed. After the pre-charge, during RESET write to a variable resistance element(s), a current needed for the RESET write can be supplied from the first source line driver circuit 56 having large current driving capability.

When the potential of the common source line 4 is controlled to transit from the VRESET potential to 0 potential prior to SET write, charges of the common source line 4 are discharged by the second source line driver circuit 58 having low current driving capability (second period during time t5 to t6 in FIG. 6). From the above, a peak current can be suppressed. After that, when the SET write is performed to the variable resistance element(s), a current needed for the SET write can be flown by the first source line driver circuit 56 having large current drive capability. As mentioned above, according to the first exemplary embodiment, such an effect is brought about that there is provided a semiconductor device in which the layout size can be reduced; and when the potential of the common source line 4 is controlled to transit, a peak current can be suppressed.

Since the RESET write and the SET write are performed after charge/discharge for the wiring capacitance of the common source line, such an effect is brought about that a steady current can be supplied, which makes it possible to transit to the desired resistance state precisely. If the RESET write or the SET write starts in the middle of the charge/discharge for the wiring capacitance, it is impossible to supply a steady current to the variable resistance element(s), so that there is a risk in which a resistance state after the writing cannot transit to the desired state, or fluctuation in the resistance state occurs.

Further, according to the first exemplary embodiment, similarly as in the conventional art disclosed in Patent Literature 1, such an effect is brought about that upon controlling the potentials of bit lines and the common source line, a large amplitude potential difference does not occur at only one side terminal. That is to say, the bit line potential transits between 0 and VRESET during RESET write; the bit line potential transits between 0 and VSET during SET write; and the common source line potential transits between 0 and VRESET. Therefore, a large amplitude potential difference does not occur at only one side terminal.

Besides, according to the first exemplary embodiment, when write-data consisting of a plurality of bits is written, the common source line 4 is controlled to transit per the plural bits. Concretely, after performing RESET write to the plurality of bits at the same time, SET write is performed, so that the frequency of switching between RESET write and SET write can be reduced. Since the frequency of pre-charge or discharge in the common source line 4 is reduced, such an effect is brought about that it is possible to speed up the writing operation.

When RESET write is performed to the plural bits at the same time, as shown in FIG. 7A, the RESET write is performed simultaneously by selecting all the column selective lines Y3_0-7, so that such an effect is brought about that it is possible to further speed up the write operation.

According to the first exemplary embodiment, as shown in FIG. 7B, a plurality of selective variable resistance memory cells are selected one by one in time series during SET write. However, as in RESET write, the SET write is simultaneously performed by simultaneously selecting the plurality of selective variable resistance memory cells. In this case, it is possible to speed up the write operation more than in FIG. 7B.

Any selection methods other than FIGS. 7(a), (b) are possible. For example, it is possible to perform controlling two times of simultaneous four bits selection or four times of simultaneous two bits selection when performing 8 bits data writing. In the first exemplary embodiment, the operation of a single memory cell mat including 512 bit lines and 512 sub word lines and 8 bits IO lines was explained. However, it is natural that the above-mentioned effects of the first exemplary embodiment are also brought in a constitution in which arbitrary number of bit lines, sub word lines, memory cell mats, and IO lines are included.

### Second Exemplary Embodiment

### Constitution of the Second Exemplary Embodiment

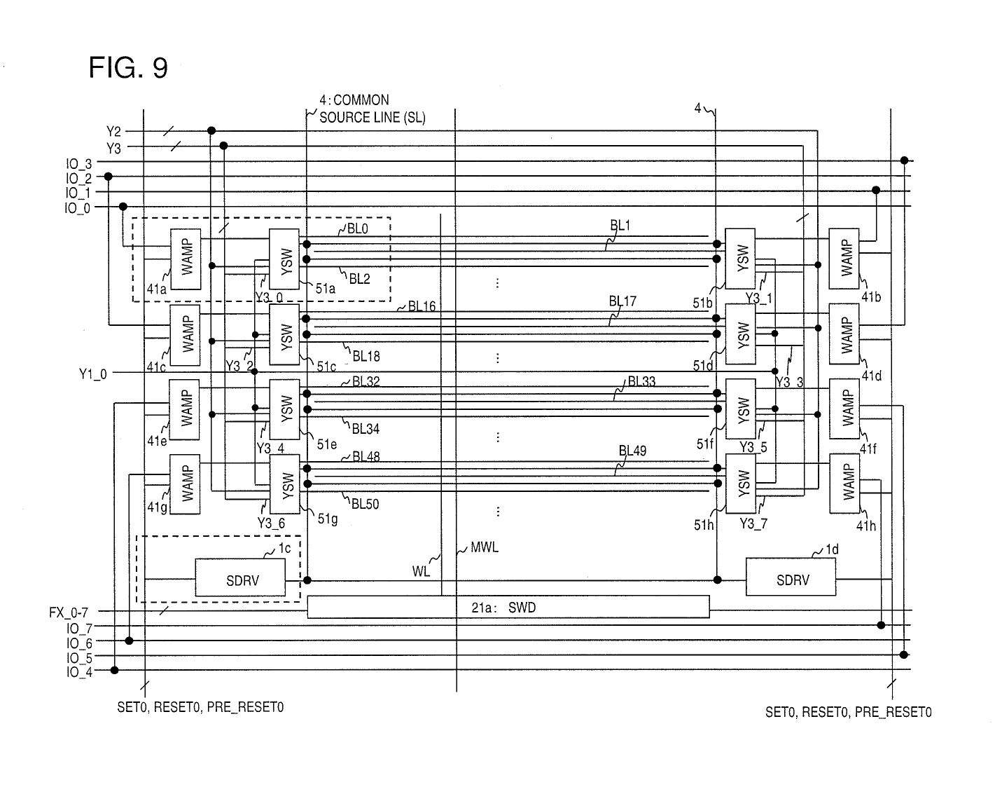

Next, the second exemplary embodiment will be described. A difference of the second exemplary embodiment from the first exemplary embodiment mainly resides in that data (IO_0-7) in IO lines are supplied to write amplifiers 41a to 41h to control, respectively. Along with the above difference point, control function using data (IO_0-7) of the IO lines in one-bit Y switches 202-204 are deleted. Meanwhile, a constitution of source line drivers and a method of controlling the source line drivers are the same as in the first exemplary embodiment. Effects brought by unifying source lines are similar to the first exemplary embodiment. By referring to FIGS. 9, 10, 11, a constitution of the second exemplary embodiment will be described in detail below.

FIG. 9 is a block diagram showing a memory cell mat (7a in FIG. 2) and its peripheral parts in accordance with the second exemplary embodiment. As seen by comparing FIG. 9 with FIG. 3 (the first exemplary embodiment), the write amplifiers 40a to 40h in FIG. 3 are replaced with the write amplifiers 41a to 40h in FIG. 9. The Y switches 50a to 50h in FIG. 3 are replaced with the Y switches 51a to 51h in FIG. 9. Since other constituent components in FIG. 9 are similar to those in FIG. 3, they are denoted by the same reference symbols, and their explanations are omitted.

In FIG. 9, IO_0 to IO_7 are supplied to the write amplifiers 41a to 41h, respectively. On the other hand, the IO_0 to IO_7 are not supplied to the Y switches 51a to 51h.

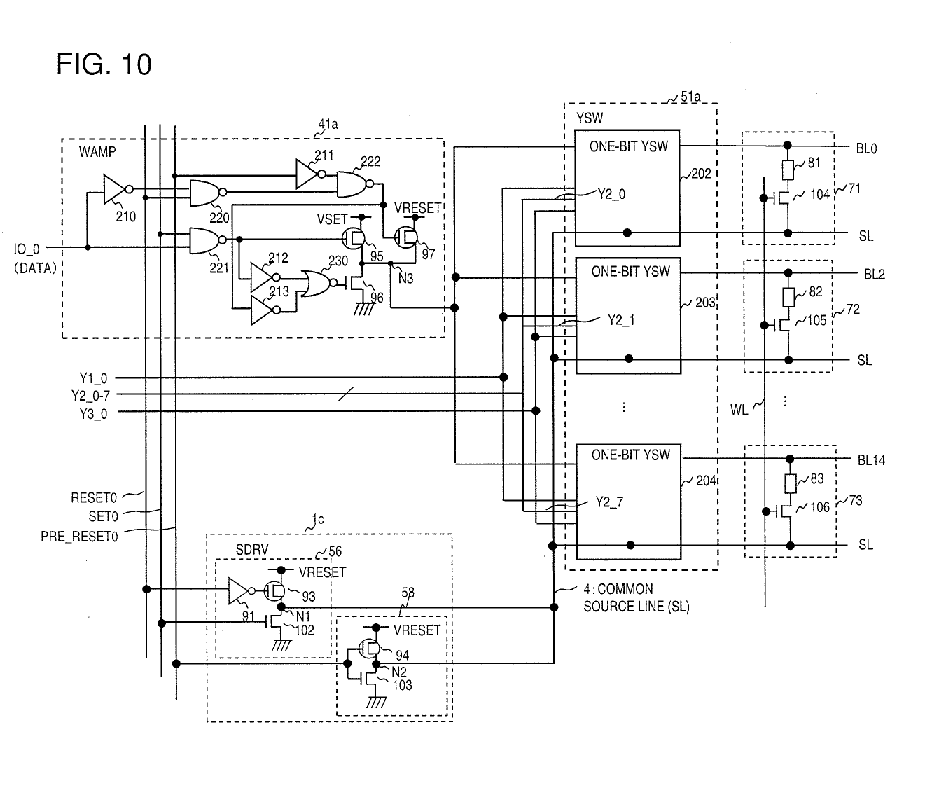

Next, FIG. 10 is a detailed block diagram showing a region of a dashed line box in FIG. 9, and shows a source line driver 1c, a write amplifier 41a, a Y switch 51a, and variable resistance memory cells (71 to 73). As can be seen by comparing FIG. 10 with FIG. 4 (the first exemplary embodiment), the write amplifier 40a in FIG. 4 is replaced with the write amplifier 41a in FIG. 10. The Y switch 50a in FIG. 4 is replaced with the Y switch 51a in FIG. 10. The one-bit Y switches 52 to 54 in the Y switch 50a in FIG. 4 are replaced with one-bit Y switches 202 to 204 in FIG. 10, respectively. Since other constituent components in FIG. 10 are similar to those in FIG. 3, they are denoted by the same reference symbols, and their explanations are omitted.

First, the write amplifier 41a shown in FIG. 10 will be described in detail. The write amplifier 41a has a function of receiving IO_0, the set signal SET0, the reset signal RESET0, and the pre-reset signal PRE_RESET0, and outputting a potential of a node N3 to one-bit Y switches 202 to 204.

As shown in FIG. 10, the write amplifier 41a includes PMOS transistors 95, 97, an NMOS transistor 96, inverter circuits 210 to 213, NAND circuits 220 to 222, and a NOR circuit 230. The PMOS transistor 95 and the NMOS transistor 96 are connected in series between the voltage source VSET and the ground. Concretely, source of the PMOS transistor 95 is connected to the voltage source VSET; drain of the PMOS transistor 95 and drain of the PMOS transistor 96 are connected to the node N3 in common; and source of the NMOS transistor 96 is connected to the ground. Source of the PMOS transistor 97 is connected to the voltage source VRESET; drain of the PMOS transistor 97 is connected to the node N3.

The IO_0 is connected to one input terminal of the NAND circuit 220 via the inverter circuit 210. A wiring of the reset signal RESET0 is connected to the other input terminal of the NAND circuit 220. One side input terminal of the NAND circuit 222 is connected to a wiring of the pre-reset signal PRE_RESET0 via the inverter circuit 211. The other input terminal of the NAND circuit 222 is connected to output terminal of the NAND circuit 220. Output terminal of the NAND circuit 222 is connected to gate of the PMOS transistor 97.

One input terminal of the NAND circuit 221 is connected to a wiring of the set signal SET0. The other input terminal of the NAND circuit 221 is connected to the IO_0. Output terminal of the NAND circuit 221 is connected to gate of the PMOS transistor 95.

One input terminal of the NOR circuit 230 is connected to the output terminal of the NAND circuit 221 via the inverter circuit 212. The other input terminal of the NOR circuit 230 is connected to output terminal of the NAND circuit 222 via the inverter circuit 213. Output terminal of the NOR circuit 230 is connected to gate of the NMOS transistor 96.

An operation based on the constitution of the above write amplifier 41a will be described later. A difference of other write amplifiers 41b to 41h in FIG. 9 from the write amplifier 41a resides in that the other write amplifiers 41b to 41h in FIG. 9 receive IO_1 to IO_7 as an IO line, respectively. In other points, the other write amplifiers 41b to 41h have the same configuration as the write amplifier 41a.

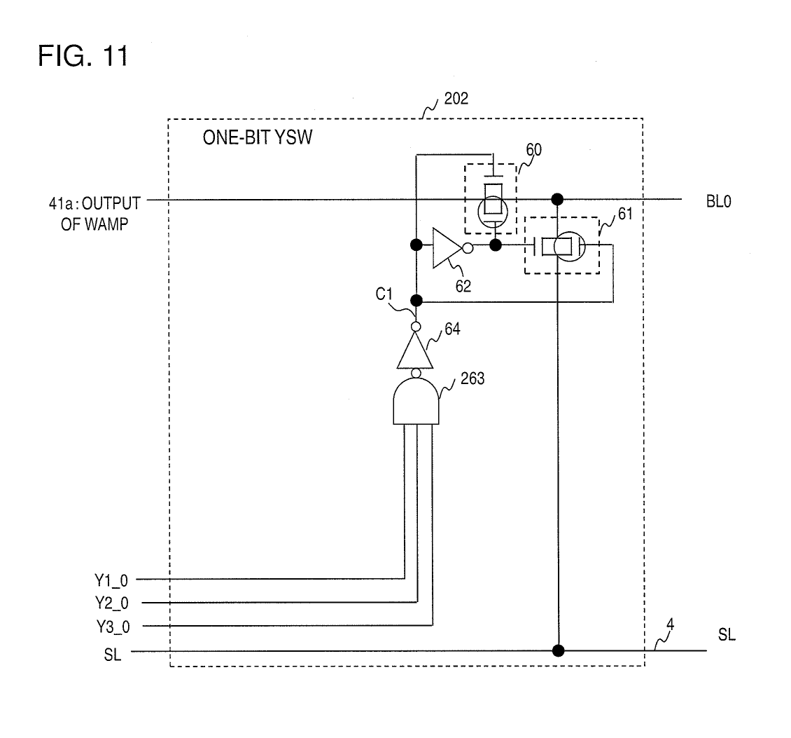

Next, FIG. 11 is a circuit diagram showing the one-bit Y switch 202 of FIG. 10 in detail. As can be seen by comparing FIG. 11 with FIG. 5 (the first exemplary embodiment), the NAND circuit 63 with four inputs in FIG. 5 is replaced with the NAND circuit 263 with three inputs in FIG. 11. Control signal C1 controlling the bit line selection switch 60 and the bit line common source line connection switch 61 is generated by the NAND circuit 263 and the inverter circuit 64 shown in FIG. 11.

In the first exemplary embodiment, during RESET write, if the IO_0 is 0, and all the Y1_0, Y2_0 and Y3_0 are 1, the control signal C0 is 1; or during SET write, if the IO_0 is 1, and all the Y1_0, Y2_0 and Y3_0 are 1, the control signal C0 is 1. As mentioned above, the control signal C0 depends on the information whether RESET write or SET write is performed (SEL in FIG. 5), and IO_0. On the other hand, in the second exemplary embodiment, if all the Y1_0, Y2_0 and Y3_0 are 1, the control signal C1 is 1; otherwise the control signal C1 is 0. As mentioned above, the control signal C1 does not depend on the information whether RESET write or SET write is performed (SEL in FIG. 5), and IO_0. Therefore, it is unnecessary to provide the SEL and IO_0 to the one-bit Y switch, so that the one-bit Y switch is realized by a simpler configuration than in the first exemplary embodiment.

FIG. 11 gives an explanation for the one-bit Y switch 202. However, other one-bit Y switches have the same circuit configuration as in FIG. 11. A difference of other one-bit Y switches from the one-bit Y switch 202 resides only in a combination of i, j, k in the supplied Y1_i, Y2_j, and Y3_k (i, j, k=0 to 7).

### Operation of the Second Exemplary Embodiment

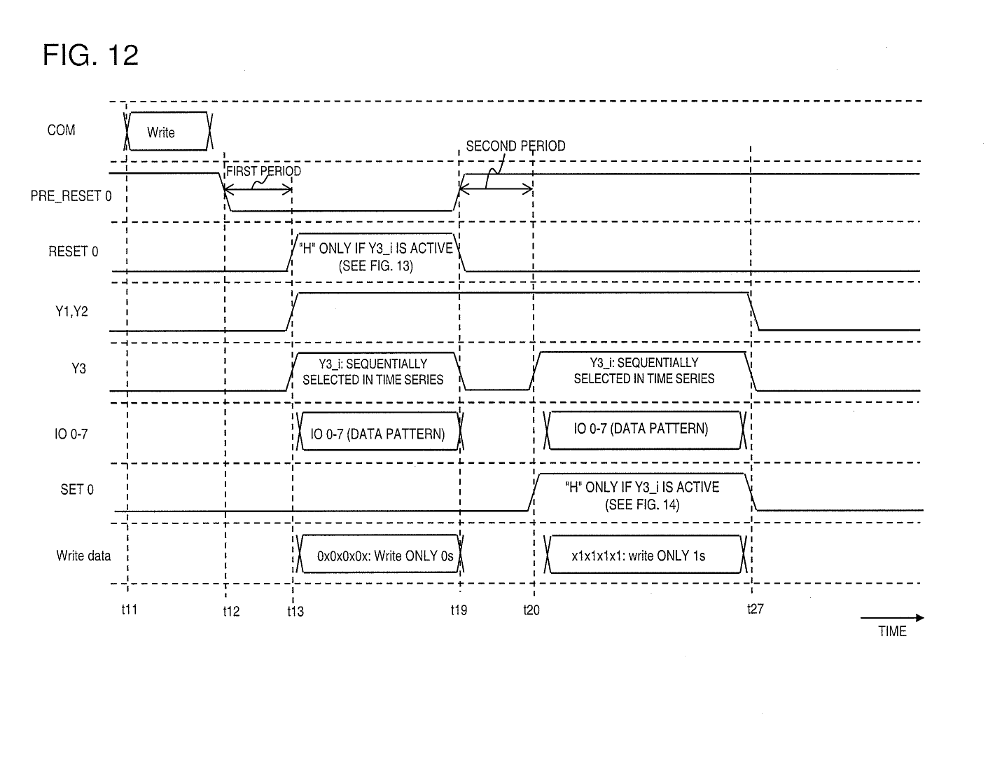

Next, by referring to FIGS. 12 to 14, an operation of the second exemplary embodiments will be described in detail. FIG. 12 is a timing chart showing an operation of the semiconductor device in accordance with the second exemplary embodiment. As an example, by referring to FIG. 12, an operation will be explained when 8 bits data (01010101) is written to variable resistance memory cells of a predetermined address in the memory cell mat including 512×512 variable resistance memory cells shown in FIG. 9. That is to say, the same situation as in FIG. 6 explaining the operation of the first exemplary embodiment is assumed.

However, the operation of the second exemplary embodiment shown in FIG. 12 is different from that in FIG. 6 (the first exemplary embodiment) in the following points. In FIG. 6, after RESET write is performed to all bits by data (00000000), SET write is performed to the SET write bits (corresponding to the IO_1, IO_3, IO_5, and IO_7). On the other hand, in FIG. 12 (the second exemplary embodiment), as shown in Write data in FIG. 12, after RESET write is performed to bits “0” of data (0x0x0x0x) (t13 to t19 in FIG. 12), SET write is performed to bits “1” of data (x1x1x1x1) (t20 to t27 in FIG. 12).

And during both the RESET write (t13 to t19 in FIG. 12) and the SET write (t20 to t27 in FIG. 12), the column selection signals Y3_j are selected one by one j=0, 1, . . . , 7 in time series.

Next, in each of the periods in FIG. 12, an operation of the write amplifier 41a to 41h shown in FIG. 10 will be described. In the time t11 to t13 (first period), and time t19 to t20 (second period) in FIG. 12, all bit lines are non-selective bit lines, and outputs of the write amplifiers 41a to 41h are not used for the potentials of bit lines. Thus, explanation of operations of the write amplifiers 41a to 41h during the above periods is omitted.

Next, operations of the write amplifiers 41a to 41h during the time t13 to t19 will be described. During this period, (PRE_RESET0, SET0)=(0,0) and the two signals are fixed. On the other hand, since the reset signal RESET0 is controlled to rise each when Y3_j is selected in time series, the reset signal RESET0 may be 0 or 1. First, if RESET0=0, only the PMOS transistors 97 in the write amplifiers 41a to 41h are in an on state, so that the write amplifiers 41a to 41h output the VRESET potential. If RESET0=1 and input (DATA) in IO lines is 0, only the NMOS transistors 96 are in an on state, so that the write amplifiers 41a to 41h output 0 potential. If RESET0=1 and input (DATA) in IO lines is 1, only the PMOS transistors 97 are in an on state, so that the write amplifiers 41a to 41h output the VRESET potential. That is to say, during the time t13 to t19, if RESET0=1 and input (DATA) in the IO lines is 0, the write amplifiers 41a to 41h output 0 potential; otherwise output the VRESET potential.

Next, operations of the write amplifiers 41a to 41h during the time t20 to t27 will be described. During this period, (PRE_RESET0, RESET0)=(1, 0), and the two signals are fixed. On the other hand, the set signal SET0 is controlled to rise each when the Y3_j is selected in time series, so that the set signal SET0 may be 0 or 1. First, if SET0=0, only the NMOS transistors 96 in the write amplifiers 41a to 41h is are an on state, so that the write amplifiers 41a to 41h output 0 potential. If SET0=1 and input (DATA) in the IO lines is 0, only the NMOS transistors 96 are in an on state, so that the write amplifiers 41a to 41h output 0 potential. If SET0=1 and input (DATA) in the IO lines is 1, only the PMOS transistors 95 are in an on state, so that the write amplifiers 41a to 41h output VSET potential. That is to say, during the time t20 to t27, if SET0=1 and input (DATA) in the IO lines is 1, the write amplifiers 41a to 41h output the VSET potential; otherwise output 0 potential.

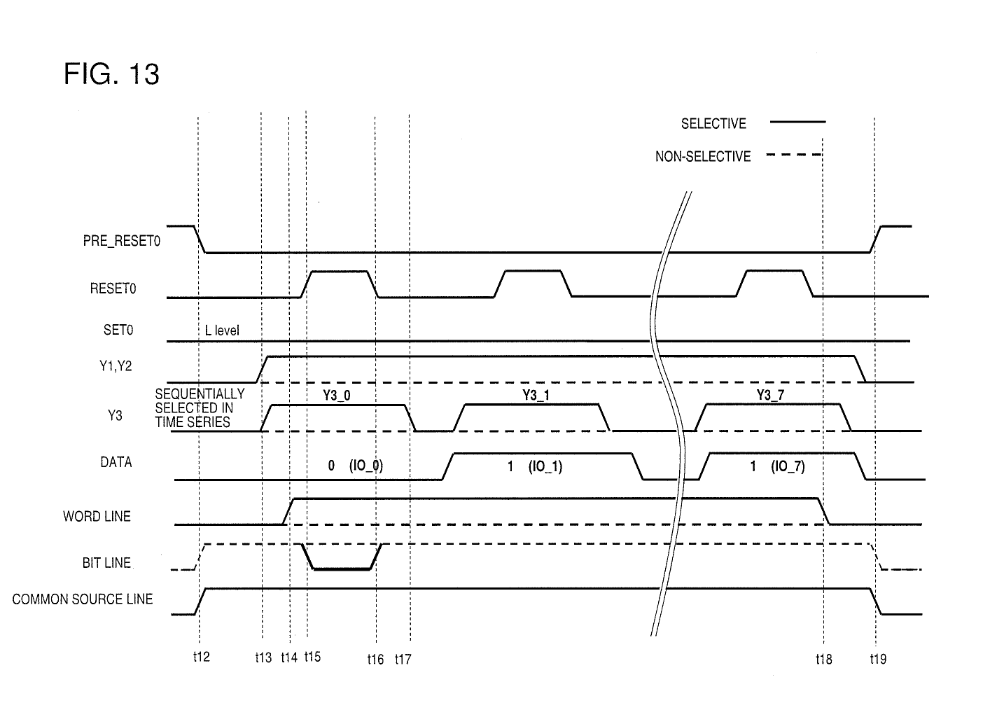

By referring to FIG. 13, an operation of the time t12 to t19 will be described below. FIG. 13 shows the detail of the time t12 to t19 of FIG. 12, and also shows operation waveforms of the word line, the bit line, and common source line 4. In the explanation of each period in FIG. 13, the output potential of the write amplifier 41a to 41h mentioned above will be referred.

In FIG. 13, the common source line 4 operates similarly to the first exemplary embodiment. Concretely, if the pre-reset signal PRE_RESET is controlled to fall down at the time t12, the common source line 4 transits from 0 potential to the VRESET potential. And if the pre-reset signal PRE_RESET is controlled to rise at the time t19, the common source line 4 transits from the VRESET potential to 0 potential. Non-selective bit lines (bit lines that are not selected by the Y1, Y2, and Y3) among the bit lines have the same potential as the common source line 4 by conduction of the bit line common source line connection switch 61 (shown as the dashed line in FIG. 13). Meanwhile, the potential of the selective bit line will be described later.

The Y1, Y2 that indicate a predetermined address to which the 8 bits data is written are set at time t13, and Y1, Y2 maintain the settings until the setting of the last Y3_j in time series is completed. On the other hand, as for the Y3_j, the Y3_0 is activated at the time t13; and after that, as shown in FIG. 13, the Y3_1 to Y3_7 are activated one by one.

DATA in FIG. 13 shows the IO_0-7 (DATA) supplied to each of the write amplifiers 41a to 41h. As the Y3_j are activated in order of j=0, 1, . . . , 7, the output of write amplifiers 41a, 41b, . . . , 41h corresponding to the respective Y3_j are respectively used as a potential of the selective bit line.

A predetermined word line among the plurality of word lines transits to a High level at time t14 to be selected. The selective word line does not need to be changed depending on the transition of Y3_j (j=0, . . . , 7), and maintains the same state until time t18, and return to the Low level at the time t18.

Next, an operation of each period in FIG. 13 will be described. First, as mentioned above, the operation of the time t12 to t13 is the same as in the time t2 to t3 (first period) of FIG. 6 (the first exemplary embodiment). Thus, the explanation is omitted.

The time period t13 to t15 shows a state in which predetermined bit lines are selected by the Y1, Y2, and Y3_0. However, at this time period, the reset signal RESET0 is still 0. The selected bit line becomes a selective bit line, and its potential is the VRESET potential (see the above-mentioned explanation part of the output potential of the write amplifier).

Next, the time period t15 to t16 is a state in which the reset signal RESET0 is 1. Since DATA is “0” during this period, the potential of the selective bit line is 0 potential (see the above-mentioned explanation part of the output potential of the write amplifier). And when the reset signal RESET0 is controlled to return to 0 at the time t16, the potential of the selective bit line returns to the VRESET potential during the time period t16 to t17. Then, the Y3_0 is non-selective at the time t17, so that the above selective bit line becomes a non-selective bit line. In the waveform illustration of the bit line in FIG. 13, the potential of the selective bit line is illustrated as a solid line (only if the potential of the bit line is different from that of the non-selective bit line, it is illustrated as a solid line), whereas the potential of the non-selective bit line is illustrated as a dashed line.

Since during the time period t15 to t16, the selective bit line is 0 potential, and the common source line 4 is the VRESET potential, a current flows from the common source line 4 to the selective bit line via the selected variable resistance memory cell, so that RESET write to the variable resistance memory cell is performed.

And if the Y3_2, Y3_4, or Y3_6 is selected to be activated, the same operation as the period of time t13 to t17 mentioned above in which the Y3_0 is activated is performed. On the other hand, if the Y3_1, Y3_3, Y3_5, or Y3_7 is activated, DATA is “1”, so that the selective bit line is the VRESET potential. Since the selective bit line is the same potential as the common source line 4, RESET write is not performed.

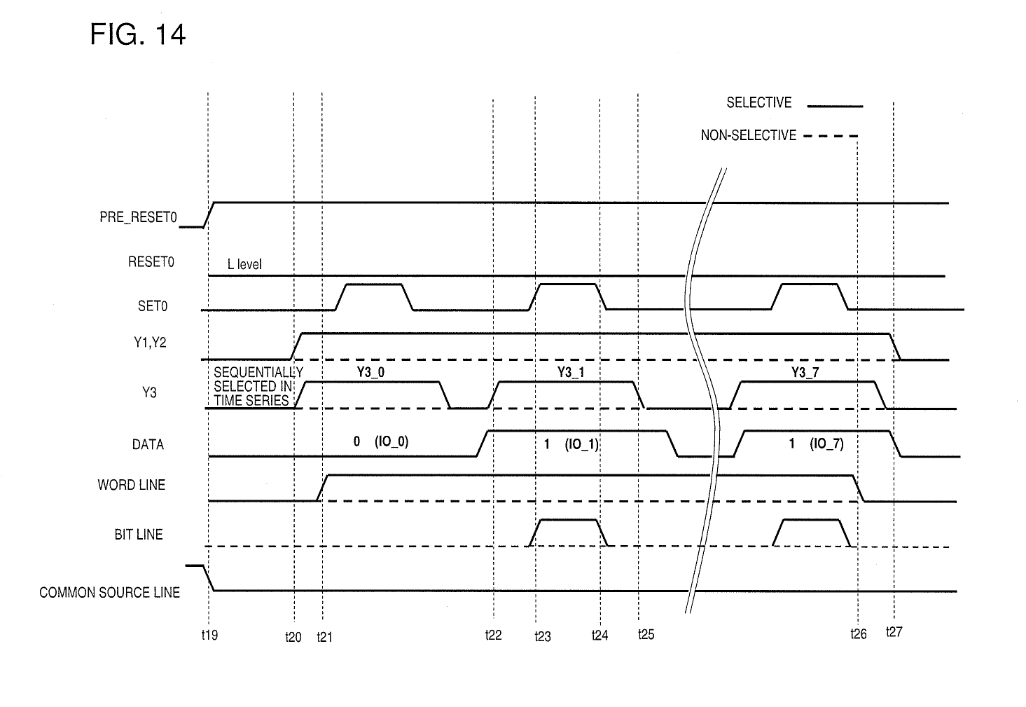

Next, an operation during the time period t19 to t27 will be described with reference to FIG. 14. FIG. 14 shows the detail of the time period t19 to t27 in FIG. 12, and also shows operation waveforms of the word line, the bit line, and the common source line 4.

In FIG. 14, the common source line 4 operates similarly to the first exemplary embodiment. Concretely, when the pre-reset signal PRE_RESET0 is controlled to rise at the time t19, the common source line 4 transits from the VRESET potential to 0 potential. The non-selective bit lines (bit lines that are not selected by the Y1, Y2, and Y3) among the bit lines have the same potential as the common source line 4 by conduction of the bit line common source line connection switch 61 (illustrated as a dashed line in FIG. 14). Meanwhile, the potential of the selective bit line will be described later.

The Y1, Y2 that indicate a predetermined address to which 8 bits data is written are set at the time t20, and the Y1, Y2 maintain the settings until the setting of the last Y3_j in time series is completed. On the other hand, as for the Y3_j, the Y3_0 is activated at the time t20; after that, as shown in FIG. 14, the Y3_1 to Y3_7 are activated one by one.

DATA in FIG. 14 shows IO_0-7 (DATA) supplied to each of the write amplifiers 41a to 41h. As the Y3_j are activated in order of j=0, 1, . . . , 7, the outputs of the write amplifiers 41a, 41b, . . . , 41h corresponding to the respective Y3_j are used as a potential of the selective bit line.

A predetermined word line corresponding to the data write among a plurality of word lines transits to a High level at the time t21 to be selected. The selective word line does not need to be changed depending on the transition of the Y3_j (j=0 to 7), and maintains the same state until the time t26, and returns to the Low level at the time t26 to be non-selective.

Next, in FIG. 14, an operation of each of the periods will be described in detail. First, an operation of the time period t19 to t20 is the same as in that of the second time period t5 to t6 in FIG. 6 (the first exemplary embodiment). Thus, the explanation is omitted.

The time period t22 to t23 is a state in which a predetermined bit line is selected by the Y1, Y2, and Y3_1. However, the set signal SET0 is still “0” at this period. And the selected bit line becomes a selective bit line, and its potential is 0 potential (see the above-mentioned explanation part of the output potential of the write amplifier).

Next, the time period t23 to t24 is a state in which the set signal SET0 is “1”. Since DATA is “1” during this period, the potential of the selective bit line is the VSET potential (see the above-mentioned explanation part of the output potential of the write amplifier). Then, if the set signal SET0 returns to “0” at the time t24, the potential of the selective bit line returns to 0 potential during the time period t24 to t25. Then, the Y3_1 is non-selective at the time t25, and the above selective bit line becomes a non-selective bit line. In waveform illustration of the bit line in FIG. 14, the potential of the selective bit line is illustrated as a solid line (only if the potential of the selective bit line is different from that of the non-selective bit line, it is illustrated as a solid line), whereas the potential of the non-selective bit line is illustrated as a dashed line.

Since during the time period t23 to t24, the selective bit line is the VSET potential, and the common source line 4 is at 0 potential, a current flows from the selective bit line to the common source line 4 via the selected variable resistance memory cell, so that SET write to the variable resistance memory cell is performed.

If the Y3_3, Y3_5, or Y3_7 is selected to be activated, the same operation as the period of time t22 to t25 mentioned above in which the Y3_1 is activated is performed. On the other hand, if the Y3_0, Y3_2, Y3_4, or Y3_6 is activated, DATA is “0”, so that the selective bit line is at 0 potential. Since, the selective bit line is the same potential as the common source line 4, SET write is not performed.

As described above, according to the semiconductor device in accordance with the second exemplary embodiment, the effects similar to the first exemplary embodiment are brought by unifying source lines. Further, according to the second exemplary embodiment, data IO_0-7 of IO lines are supplied to the write amplifiers 41a to 41h; during RESET write, only if the write bit corresponds to the selective bit line and DATA=“0”, the write amplifier outputs 0 potential that is different from the common source line 4; and during a set write, only if the write bit corresponds to the selective bit line and DATA=“1”, the write amplifier outputs the VSET potential that is different from the common source line 4. Therefore, such an effect is brought about that the constitution and control of the Y switches (including one-bit Y switches) can be simplified.

Meanwhile, in the second exemplary embodiment, as shown in FIGS. 12-14, bits for RESET write are selected and the RESET writes for the bits are performed in time series; after that, bits for SET write are selected and the SET writes for the bits are performed in time series. However, the method of the present disclosure is not limited to the above operation. For example, in the constitution of the second exemplary embodiment, if it is controlled so that data of IO lines (IO_0-7) is set to be (00000000) during RESET write, and the Y3_0 to Y3_7 are selected at the same time, it is possible to operate similarly to FIG. 6 explained in the first exemplary embodiment.

The semiconductor device according to the preset disclosure can be applied to a semiconductor device including non-volatile memory cells (for example, PRAM, STT-RAM). According to the present disclosure, it is sufficient that the variable resistance element used in the semiconductor device is an element the resistance value of which is variable by passing a current through its resistance element regardless of its operating principle.

The exemplary embodiments and examples may include variations and modifications without departing the gist and scope of the present invention as disclosed herein and claimed as appended herewith, and furthermore based on the fundamental technical spirit. It should be noted that any combination and/or selection of the disclosed elements may fall within the claims of the present invention. That is, it should be noted that the present invention of course includes various variations and modifications that could be made by those skilled in the art according to the overall disclosures including claims and technical spirit.

What is claimed is:

1. A semiconductor device, comprising:
a plurality of variable resistance memory cells;
a plurality of bit lines each of which is connected to one end of each of said plurality of variable resistance memory cells;
a common source line that is connected to the other ends of said plurality of variable resistance memory cells in common;
a source line driver that supplies a potential to said common source line; and
a controller that variably controls a current supplied to said common source line by said source line driver.

2. The semiconductor device according to claim 1, wherein
said source line driver includes:
a first source line driver circuit connected to said common source line; and
a second source line driver circuit connected to said common source line,
current drive capability of a transistor included in said second source line driver circuit being less than that of a transistor included in said first source line driver circuit.

3. The semiconductor device according to claim 1, further comprising:
a write amplifier that in a case where a variable resistance memory cell is selected among said plurality of variable resistance memory cells to be written, supplies a potential to a selective bit line that is a bit line connected to said selected variable resistance memory cell.

4. The semiconductor device according to claim 2, further comprising:
a write amplifier that in a case where a variable resistance memory cell is selected among said plurality of variable resistance memory cells to be written, supplies a potential to a selective bit line that is a bit line connected to said selected variable resistance memory cell.

5. The semiconductor device according to claim 3, wherein
in a case where said selected variable resistance memory cell is written so as to transit to a first resistance state,
said controller controls so that said second source line driver circuit pre-charges said common source line to a High level during a predetermined first period; said write amplifier supplies a Low level to said selective bit line; and said first source line driver circuit supplies the High level potential to said common source line after the first period.

6. The semiconductor device according to claim 5, wherein
in a case where said selected variable resistance memory cell is written so as to transit to a second resistance state different from said first resistance state,
said controller controls so that said second source line driver circuit discharges said common source line to a Low level during a predetermined second period; said write amplifier supplies a High level to said selective bit line; and said first source line driver circuit supplies the Low level potential to said common source line after the second period.

7. The semiconductor device according to claim 5, writing write-data consisting of a plurality of bits, wherein
said controller controls so that a potential of said common source line transits per said plurality of bits.

8. The semiconductor device according to claim 6, writing write-data consisting of a plurality of bits, wherein
said controller controls so that a potential of said common source line transits per said plurality of bits.

9. The semiconductor device according to claim 8, wherein
said controller controls so that after a plurality of said variable resistance memory cells selected corresponding to said plurality of bits are all written to the first resistance state, said variable resistance memory cell corresponding to a bit in said write-data which corresponds to the second resistance state among the plurality of said variable resistance memory cells selected corresponding to said plurality of bits is written to transit to the second resistance state.

10. The semiconductor device according to claim 8, wherein
said controller controls so that after a plurality of said variable resistance memory cells selected corresponding to said plurality of bits are all written to the second resistance state, said variable resistance memory cell corresponding to a bit in said write-data which corresponds to the first resistance state among the plurality of said variable resistance memory cells selected corresponding to said plurality of bits is written to transit to the first resistance state.

11. The semiconductor device according to claim 1, wherein
said plurality of variable resistance memory cells constitute a plurality of memory cell mats, and said common source line is arranged in each region including one or more memory cell mats.

12. The semiconductor device according to claim 11, comprising a plurality of said source line drivers, wherein
at least one of said source line drivers is arranged for each of said memory cell mats.

13. A semiconductor device comprising:
a plurality of bit lines;
a source line;
a plurality of word lines crossing the bit lines to define a plurality of intersections;
a plurality of memory cells each arranged at a corresponding one of the intersections, each of the memory cells including a variable resistance element and a cell transistor coupled in series between the source line and a corresponding one of the bit lines; and
a source line driver configured to drive the source line with supplying a first current in a first mode and to drive the source line with supplying a second current in a second mode, the second current being greater than the first current.

14. The semiconductor device according to claim 13, wherein the source line driver includes a first driver driving the source line in both the first and second modes and a second driver, the second driver driving the source line in the second mode and not driving the source line in the first mode.

15. The semiconductor device according to claim 14, wherein the second driver is greater in size than the first driver.

16. The semiconductor device according to claim 14, wherein the first and second drivers are configured to receive first and second control signals, respectively, the first control signal being activate in both the first and second modes, the second control signal being inactivate in the first mode and activate in the second mode.

17. The semiconductor device according to claim 13, further comprising:
a plurality of additional bit lines;
an additional source line;
a plurality of additional word lines crossing the additional bit lines to define a plurality of additional intersections;
a plurality of additional memory cells each arranged at a corresponding one of the additional intersections, each of the additional memory cells including an additional variable resistance element and an additional cell transistor coupled in series between the source line and a corresponding one of the additional bit lines; and
an additional source line driver configured to drive the additional source line with supplying the first current in the first mode and to drive the additional source line with supplying the second current in the second mode.

18. The semiconductor device according to claim 17, wherein the source line and the additional source line are electrically coupled to each other.

19. The semiconductor device according to claim 17, wherein the source line driver includes a first driver driving the source line in both the first and second modes and a second driver, the second driver driving the source line in the second mode and not driving the source line in the first mode, the additional source line driver including an additional first driver driving the additional source line in both the first and second modes and an additional second driver, the additional second driver driving the additional source line in the second mode and not driving the additional source line in the first mode.

20. The semiconductor device according to claim 19, wherein the first driver and the additional first driver are configured to be controlled in common by a first control signal and the second driver and the additional second driver are configured to be controlled in common by a second control signal.
